(19) United States
(12) Patent Application Publication
(10) Pub. No.: US 2025/0174439 A1
(43) Pub. Date: May 29, 2025

(54) SUBSTRATE PROCESSING APPARATUS

(71) Applicant: Tokyo Electron Limited, Tokyo (JP)

(72) Inventors: Koji AKIYAMA, Nirasaki City, Yamanashi (JP); Hirokazu UEDA, Osaka City, Osaka (JP); Toshikazu AKIMOTO, Tokyo (JP); Naoki UMESHITA, Tokyo (JP); Ryuichi ASAKO, Nirasaki City, Yamanashi (JP); Kazuyoshi MATSUZAKI, Nirasaki City, Yamanashi (JP)

(21) Appl. No.: 18/842,575

(22) PCT Filed: Feb. 16, 2023
(86) PCT No.: PCT/JP2023/005368

§ 371 Date: Aug. 29, 2024

(30) Foreign Application Priority Data
Mar. 2, 2022 (JP) 2022-031761

(51) Int. Cl. H01J 37/32; H01L 21/67

(52) U.S. Cl. CPC H01J 37/3244; H01L 21/67017; H01J 2237/332

(57) ABSTRACT

A substrate processing apparatus includes a processing container in which a substrate to be processed is accommodated and substrate processing is performed, a liquid supplier configured to supply a first ionic liquid to an interior of the processing container, a liquid recoverer configured to recover the first ionic liquid from the interior of the processing container, a connection pipe configured to connect the liquid recoverer to the liquid supplier, and a gas supplier configured to supply gas to the connection pipe to send the first ionic liquid to the liquid supplier from the liquid recoverer by a gas lift pump action of the gas which rises.

### TECHNICAL FIELD

The present disclosure relates to a substrate processing apparatus.

### BACKGROUND

There is known a technique for supplying ionic liquid into a vacuum chamber of a semiconductor manufacturing device (see Patent Documents 1 and 2).

### PRIOR ART DOCUMENT

### Patent Documents

Patent Document 1: Japanese Laid-Open Patent Publication No. 2020-088282
Patent Document 2: Japanese Laid-Open Patent Publication No. 2014-239220

### SUMMARY

The present disclosure provides some embodiments of a technique capable of supplying liquid to a vacuum chamber of a semiconductor manufacturing device without mechanical power.

A substrate processing apparatus according to an aspect of the present disclosure includes a processing container in which a substrate to be processed is accommodated and substrate processing is performed, a liquid supplier configured to supply a first ionic liquid to an interior of the processing container, a liquid recoverer configured to recover the first ionic liquid from the interior of the processing container, a connection pipe configured to connect the liquid recoverer to the liquid supplier, and a gas supplier configured to supply gas to the connection pipe to send the first ionic liquid to the liquid supplier from the liquid recoverer by a gas lift pump action of the gas which rises.

According to the present disclosure, it is possible to supply liquid to a vacuum chamber of a semiconductor manufacturing device without mechanical power.

### BRIEF DESCRIPTION OF DRAWINGS

FIG. 1 is a schematic cross-sectional view illustrating a substrate processing apparatus according to a first embodiment.

FIG. 2 is a schematic cross-sectional view illustrating a substrate processing apparatus according to a second embodiment.

FIG. 3 is a schematic cross-sectional view illustrating a substrate processing apparatus according to a third embodiment.

FIG. 4 is a schematic cross-sectional view illustrating a substrate processing apparatus according to Modification of the third embodiment.

### DETAILED DESCRIPTION

Hereinafter, non-limitative exemplary embodiments of the present disclosure will now be described with reference to the accompanying drawings. In all the accompanying drawings, the same or corresponding members or components will be denoted by the same or corresponding reference numerals, and redundant explanations thereof will be omitted.

### First Embodiment

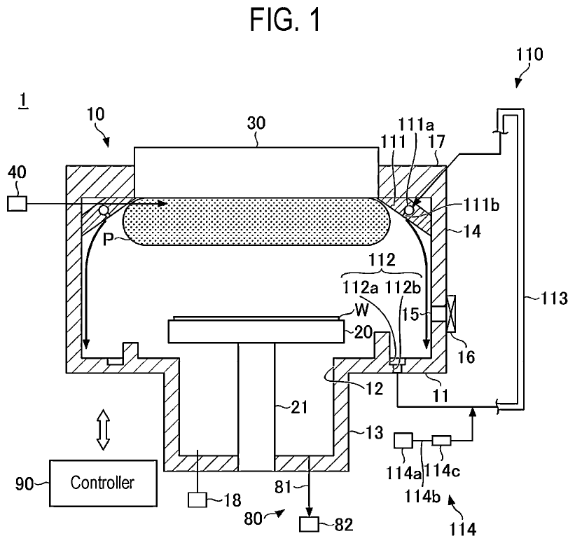

A substrate processing apparatus 1 according to a first embodiment will now be described with reference to FIG. 1. The substrate processing apparatus 1 according to the first embodiment is configured as a plasma processing apparatus. However, the substrate processing apparatus 1 is not limited to the plasma processing apparatus. The substrate processing apparatus 1 may be any apparatus in which substrate processing is performed, and may be, for example, a film forming apparatus, a plating apparatus, or a coating apparatus.

The substrate processing apparatus 1 may be preferably used in a process of forming an oxide film (plasma processing method) by oxidation processing at a low temperature of, for example, 500 degrees C. or less. An example of the oxide film may include silicon dioxide (SiO2). Further, examples of the oxide film may include a high dielectric film (high-k film) such as aluminum oxide (Al₂O₃), zirconium oxide (ZrO₂), hafnium oxide (HfO₂), strontium titanate (STO; SrTiO₃), and barium titanate (BTO; BaTiO₃).

The substrate processing apparatus 1 includes a chamber 10, a stage 20, a microwave introduction mechanism 30, a gas supplier 40, a liquid circulator 110, an exhauster 80, and a controller 90.

The chamber 10 is formed in a substantially cylindrical shape. An opening 12 is formed in a substantially central portion of a bottom wall 11 of the chamber 10. The bottom wall 11 is provided with an exhaust chamber 13 that communicates with the opening 12 and protrudes downward. A loading/unloading port 15 through which a substrate W passes is formed in a sidewall 14 of the chamber 10. The loading/unloading port 15 is open and closed by a gate valve 16. The chamber 10, together with a portion of the microwave introduction mechanism 30, constitutes a processing container whose interior is capable of being depressurized. The substrate W to be processed is accommodated in the processing container. The substrate W is, for example, a semiconductor wafer. The chamber 10 is provided with a pressure sensor 18 configured to detect an internal pressure of the chamber 10. A detection value by the pressure sensor 18 is sent to the controller 90.

The stage 20 is a placement table on which the substrate W to be processed is placed. The stage 20 has a substantially disk shape. The stage 20 is made of a ceramic such as aluminum nitride (AlN). The stage 20 is supported by a support 21 made of ceramic such as AlN of a substantially cylindrical shape which extends upward from substantially the center of the bottom of the exhaust chamber 13.

The microwave introduction mechanism 30 is provided at an upper portion of the chamber 10. The microwave introduction mechanism 30 supplies microwaves to the interior of the chamber 10. The microwave introduction mechanism 30 includes a microwave outputter, a microwave transmitter, and a microwave radiator. The microwaves are output from the microwave outputter and are introduced into the chamber 10 via the microwave transmitter and the microwave radiator. A frequency of the microwaves is, for example, 300 MHz to 10 GHz.

The gas supplier 40 supplies plasma-excitation gas below a ceiling wall 17 of the chamber 10. The gas supplier 40 may include, for example, a gas nozzle provided to penetrate the sidewall 14 of the chamber 10. The plasma-excitation gas is supplied from the gas supplier 40 and is excited by the microwaves to generate plasma P. An example of the plasma-excitation gas may include a noble gas such as argon (Ar), krypton (Kr), or xenon (Xe).

The liquid circulator 110 includes a liquid supplier 111, a liquid recoverer 112, a connection pipe 113, and a gas supplier 114.

The liquid supplier 111 is fixed to the sidewall 14 and the ceiling wall 17 of the chamber 10. The liquid supplier 111 is provided along a circumferential direction of the chamber 10. A first flow path 111a and a second flow path 111b are formed in the liquid supplier 111.

The first flow path 111a is formed inside the liquid supplier 111 along the circumferential direction of the chamber 10. The first flow path 111a has an annular shape. A first ionic liquid IL1 is supplied to the first flow path 111a from the connection pipe 113. The first ionic liquid IL1 will be described later in detail.

The second flow path 111b has one end communicating with the first flow path 111a and the other end communicating with the interior of the chamber 10. The first ionic liquid IL1 is supplied to the second flow path 111b from the first flow path 111a. The first ionic liquid IL1 supplied from the first flow path 111a flows to the interior of the chamber 10 via the second flow path 111b. The first ionic liquid IL1 supplied to the interior of the chamber 10 flows along an inner surface of the sidewall 14 to the bottom wall 11. At this time, the first ionic liquid IL1 forms a liquid film on the inner surface of the sidewall 14. The liquid film protects the sidewall 14 from corrosion when the substrate processing (e.g., plasma processing) is performed inside the chamber 10.

A plurality of second flow paths 111b may be provided at intervals in the circumferential direction of the chamber 10. In this case, the first ionic liquid IL1 is supplied at multiple positions in the circumferential direction of the chamber 10, so that the first ionic liquid IL1 flows over a wide range of the inner surface of the sidewall 14. Thus, the liquid film is formed over the wide range of the inner surface of the sidewall 14. A groove (not shown) that allows the first ionic liquid IL1 to flow in the circumferential direction of the chamber 10 may be formed in the inner surface of the sidewall 14. In this case, the first ionic liquid IL1 flows over the wide range of the inner surface of the sidewall 14. As a result, the liquid film is formed over the wide range on the inner surface of the sidewall 14.

As described above, the liquid supplier 111 supplies the first ionic liquid IL1 to the interior of the chamber 10 from the vicinity of the ceiling wall 17 of the chamber 10.

The liquid recoverer 112 is provided vertically below the liquid supplier 111. The liquid recoverer 112 has a discharge groove 112a and a discharge hole 112b. The discharge groove 112a is formed in an annular shape in the bottom wall 11. The discharge groove 112a guides the first ionic liquid IL1 that has reached the bottom wall 11 to the discharge hole 112b. The discharge hole 112b is formed in a bottom surface of the discharge groove 112a and is connected to the connection pipe 113 via the bottom wall 11. The first ionic liquid IL1 that has reached the discharge groove 112a flows into the connection pipe 113 via the discharge hole 112b. In this way, the liquid recoverer 112 recovers the first ionic liquid IL1 from the interior of the chamber 10 and causes the first ionic liquid IL1 to flow into the connection pipe 113.

The connection pipe 113 connects the liquid recoverer 112 to the liquid supplier 111. Specifically, the connection pipe 113 has one end communicating with the discharge hole 112b of the liquid recoverer 112 and the other end communicating with the first flow path 111a of the liquid supplier 111.

The gas supplier 114 includes a source 114a, a supply pipe 114b, and a flow rate controller 114c. The source 114a is a source of gas. The gas includes an inert gas such as argon. The supply pipe 114b has one end connected to the source 114a and the other end connected to the connection pipe 113. The supply pipe 114b supplies gas to the first ionic liquid IL1 flowing through the connection pipe 113 so that the first ionic liquid IL1 flows to the first flow path 111a by a gas lift pump action of the gas which rises. Specifically, the gas supplier 114 injects gas into a lower portion of the connection pipe 113 so as to send the first ionic liquid IL1 to the first flow path 111a located above the connection pipe 113 by reducing a specific gravity of the first ionic liquid IL1 inside the connection pipe 113 and using a rising force of gas bubbles. The flow rate controller 114c controls a flow rate of gas flowing through the supply pipe 114b. The flow rate controller 114c is, for example, a mass flow controller. As described above, the gas supplier 114 supplies the gas from the source 114a to the connection pipe 113 via the supply pipe 114b and sends the first ionic liquid IL1 from the discharge hole 112b to the first flow path 111a by the gas lift pump action of the rising gas.

Thus, the liquid circulator 110 sends the first ionic liquid IL1 recovered from the interior of the chamber 10 by the liquid recoverer 112 to the liquid supplier 111 via the connection pipe 113, and supplies the first ionic liquid IL1 to the interior of the chamber 10 by the liquid supplier 111. In other words, the liquid circulator 110 recovers the first ionic liquid IL1 from the interior of the chamber 10 and supplies the recovered first ionic liquid IL1 to the interior of the chamber 10, thereby circulating the first ionic liquid IL1.

The exhauster 80 includes an exhaust pipe 81 and an exhaust device 82. The exhaust pipe 81 is provided on a bottom wall of the exhaust chamber 13. The exhaust device 82 is connected to the exhaust pipe 81. The exhaust device 82 includes a vacuum pump, a pressure control valve and the like, and exhausts the interior of the chamber 10 via the exhaust pipe 81 to depressurize the chamber 10.

The controller 11 includes a memory, a processor, an input/output interface and the like. The memory stores a program executed by the processor and a recipe including each processing condition. The processor executes the program read from the memory and controls each part of the substrate processing apparatus 1 via the input/output interface based on the recipe stored in the memory.

As described above, the substrate processing apparatus 1 according to the first embodiment includes the liquid supplier 111, the liquid recoverer 112, the connection pipe 113, and the gas supplier 114. The connection pipe 113 connects the first flow path 111a of the liquid supplier 111 to the discharge hole 112b of the liquid recoverer 112. The gas supplier 114 supplies the gas to the connection pipe 113 to send the first ionic liquid IL1 from the discharge hole 112b to the first flow path 111a by the gas lift pump action of the rising gas. This makes it possible to recover the first ionic liquid IL1 from the interior of the chamber 10 and supply the recovered first ionic liquid IL1 to the interior of the chamber 10 without mechanical power. That is, the first ionic liquid IL1 may be circulated without the mechanical power. In addition, there is no need to provide a complicated liquid transport pump mechanism. This makes it possible to significantly reduce the overall cost of a system, and maintain performance of the ionic liquid when the apparatus is in operation. Therefore, a maintenance time may be shortened, and a downtime required for regeneration to maintain the performance of the circulating ionic liquid may be shortened. As described above, the substrate processing apparatus 1 according to the first embodiment may maintain throughput without reducing an operation time of the apparatus.

In the first embodiment, the case in which the plasma P is generated by the microwave introduction mechanism 30 has been described. However, the present disclosure is not limited thereto. For example, the plasma P may be generated by an inductively coupled plasma generation mechanism or a capacitively coupled plasma generation mechanism. The inductively coupled plasma generation mechanism may include a radio-frequency power source, a coil and the like. Radio-frequency current is supplied from the radio-frequency power source to the coil, so that the plasma-excitation gas supplied to the interior of the chamber 10 is excited to generate the plasma P. The capacitively coupled plasma generation mechanism may include a radio-frequency power source, an electrode, and the like. Radio-frequency current is supplied from the radio-frequency power source to the electrode, so that the plasma-excitation gas supplied to the interior of the chamber 10 is excited to generate the plasma P.

### Second Embodiment

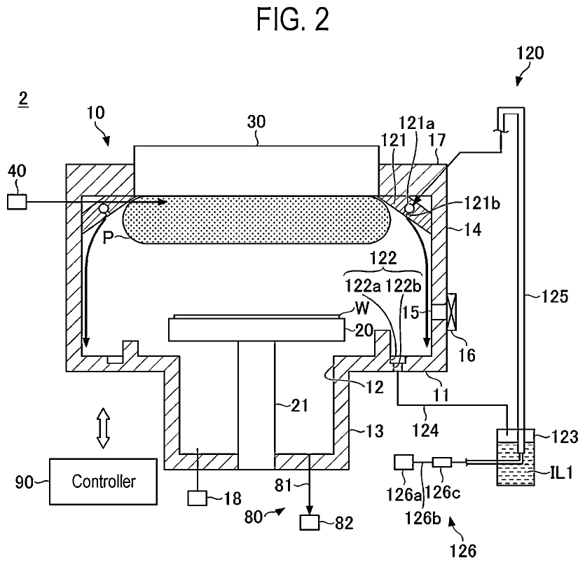

A substrate processing apparatus 2 according to a second embodiment will now be described with reference to FIG. 2. The substrate processing apparatus 2 according to the second embodiment includes a liquid circulator 120 instead of the liquid circulator 110. Other configurations are identical to those of the substrate processing apparatus 1.

The liquid circulator 120 includes a liquid supplier 121, a liquid recoverer 122, a lower tank 123, a recovery pipe 124, a connection pipe 125, and a gas supplier 126.

The liquid supplier 121 may have the same configuration as the liquid supplier 111. That is, a first flow path 121a and a second flow path 121b are formed in the liquid supplier 121.

The liquid recoverer 122 may have the same configuration as the liquid recoverer 112. That is, the liquid recoverer 122 includes a discharge groove 122a and a discharge hole 122b.

The interior of the lower tank 123 is in communication with the discharge hole 122b via the recovery pipe 124. The lower tank 123 stores the first ionic liquid IL1 discharged via the discharge hole 122b. The lower tank 123 is provided vertically below the discharge hole 122b. As a result, the first ionic liquid IL1 flows by own weight thereof from the discharge hole 122b into the interior of the lower tank 123. The lower tank 123 may be directly connected to the discharge hole 122b without passing through the recovery pipe 124.

The recovery pipe 124 has one end communicating with the discharge hole 122b and the other end inserted into the interior of the lower tank 123. For example, the other end of the recovery pipe 124 is inserted into the lower tank 123 from an upper portion of the lower tank 123. The recovery pipe 124 sends the first ionic liquid IL1 from the discharge hole 122b to the interior of the lower tank 123.

The connection pipe 125 connects the lower tank 123 to the liquid supplier 121.

Specifically, the connection pipe 125 has one end communicating with the interior of the lower tank 123 and the other end communicating with the first flow path 121a of the liquid supplier 121. For example, one end of the connection pipe 125 is inserted below a liquid level of the first ionic liquid IL1 stored inside the lower tank 123 from the upper portion of the lower tank 123.

The gas supplier 126 includes a source 126a, a supply pipe 126b, and a flow rate controller 126c. The source 126a is a source of gas. The gas includes an inert gas such as argon. The supply pipe 126b has one end connected to the source 126a and the other end inserted into the interior of the lower tank 123. The supply pipe 126b is bent, for example, in an L-shape and positioned directly below a lower end of the connection pipe 125. The supply pipe 126b supplies the gas to the first ionic liquid IL1 flowing through the connection pipe 125 so as to send the first ionic liquid IL1 to the first flow path 121a by a gas lift pump action of the gas which rises. Specifically, the gas supplier 126 injects the gas into a lower portion of the connection pipe 125 so as to send the first ionic liquid IL1 to the first flow path 121a located above the connection pipe 125 by reducing the specific gravity of the first ionic liquid IL1 inside the connection pipe 125 and using the rising force of gas bubbles. The supply pipe 126b may be connected in the connection pipe 125 inside or outside the lower tank 123. The flow rate controller 126c controls a flow rate of the gas flowing through the supply pipe 126b. The flow rate controller 126c is, for example, a mass flow controller. As described above, the gas supplier 126 supplies the gas from the source 126a to the connection pipe 125 via the supply pipe 126b and sends the first ionic liquid IL1 from the lower tank 123 to the first flow path 121a by the gas lift pump action of the rising gas.

Thus, the liquid circulator 120 sends the first ionic liquid IL1, which is recovered from the interior of the chamber 10 by the liquid recoverer 122 and stored in the lower tank 123, to the liquid supplier 121 via the connection pipe 125 and supplies the same to the interior of the chamber 10 by the liquid supplier. In other words, the liquid circulator 120 recovers the first ionic liquid IL1 from the interior of the chamber 10 and supplies the recovered first ionic liquid IL1 to the interior of the chamber 10, thereby circulating the first ionic liquid IL1.

As described above, the substrate processing apparatus 2 according to the second embodiment includes the liquid supplier 121, the liquid recoverer 122, the lower tank 123, the recovery pipe 124, the connection pipe 125, and the gas supplier 126. The connection pipe 125 connects the first flow path 121a of the liquid supplier 121 to the interior of the lower tank 123. The gas supplier 126 supplies the gas to the connection pipe 125 so as to send the first ionic liquid IL1 from the interior of the lower tank 123 to the first flow path 121a by the gas lift pump action of the rising gas. This makes it possible to recover the first ionic liquid IL1 from the interior of the chamber 10 and supply the recovered first ionic liquid IL1 to the interior of the chamber 10 without the mechanical power. That is, the first ionic liquid IL1 may be circulated without the mechanical power. In addition, like the substrate processing apparatus 1 according to the first embodiment, the substrate processing apparatus 2 according to the second embodiment may maintain throughput without reducing an operation time of the apparatus.

### Third Embodiment

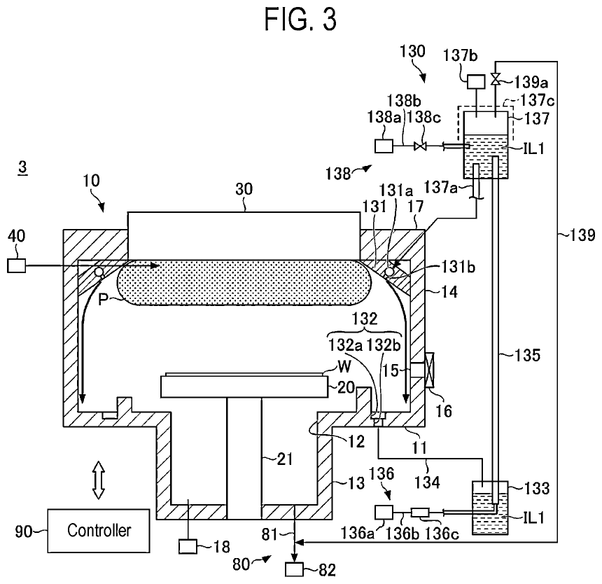

A substrate processing apparatus 3 according to a third embodiment will now be described with reference to FIG. 3. The substrate processing apparatus 3 according to the third embodiment includes a liquid circulator 130 instead of the liquid circulator 120. Other configurations are the same as those of the substrate processing apparatus 2.

The liquid circulator 130 includes a liquid supplier 131, a liquid recoverer 132, a lower tank 133, a recovery pipe 134, a connection pipe 135, a gas supplier 136, an upper tank 137, a liquid replenisher 138, and a bypass pipe 139.

The liquid supplier 131 may have the same configuration as the liquid supplier 121. That is, a flow path 131a and a second flow path 131b are formed in the liquid supplier 131.

The liquid recoverer 132 may have the same configuration as the liquid recoverer 122. That is, the liquid recoverer 132 includes a discharge groove 132a and a discharge hole 132b.

The lower tank 133 may have the same configuration as the lower tank 123.

The recovery pipe 134 may have the same configuration as the recovery pipe 124.

The connection pipe 135 connects the lower tank 133 to the upper tank 137. Specifically, the connection pipe 135 has one end communicating with the interior of the lower tank 133 and the other end communicating with the interior of the upper tank 137. For example, one end of the connection pipe 135 is inserted into the interior of the lower tank 133 from an upper portion of the lower tank 133. For example, the other end of the connection pipe 135 is inserted below a liquid level of the first ionic liquid IL1 stored inside the upper tank 137 from a lower portion of the upper tank 137.

The gas supplier 136 includes a source 136a, a supply pipe 136b, and a flow rate controller 136c. The source 136a is a source of gas. The gas includes an inert gas such as argon. The supply pipe 136b has one end connected to the source 136a and the other end inserted into the interior of the lower tank 133. The supply pipe 136b is bent, for example, in an L-shape, and positioned directly below a lower end of the connection pipe 135. The supply pipe 136b supplies the gas to the first ionic liquid IL1 flowing through the connection pipe 135 so as to send the first ionic liquid IL1 to the upper tank 137 by the gas lift pump action of the rising gas. Specifically, the gas supplier 136 injects the gas into a lower portion of the connection pipe 135 so as to send the first ionic liquid IL1 to the upper tank 137 located above the connection pipe 135 by reducing the specific gravity of the first ionic liquid IL1 inside the connection pipe 135 and using the rising force of gas bubbles. The supply pipe 136b may be connected in the connection pipe 135 inside or outside the lower tank 133. The flow rate controller 136c controls a flow rate of the gas flowing through the supply pipe 136b. The flow rate controller 136c is, for example, a mass flow controller. In this way, the gas supplier 136 supplies the gas from the source 136a to the connection pipe 135 via the supply pipe 136b and sends the first ionic liquid IL1 from the lower tank 133 to the upper tank 137 by the gas lift pump action of the rising gas.

The gas may include a first reaction gas precipitated by reacting with impurities contained in the first ionic liquid IL1. In this case, when the first ionic liquid IL1 flowing through the connection pipe 135 contains impurities, the first reaction gas is precipitated by reacting with the impurities contained in the first ionic liquid IL1. The precipitate settles, for example, in the upper tank 137. This makes it possible to remove the impurities contained in the first ionic liquid IL1. For example, when the impurities contained in the first ionic liquid IL1 are metal contaminants such as iron (Fe), sodium (Na), potassium (K), calcium (Ca), magnesium (Mg), nickel (Ni) or the like, carbon dioxide gas may be suitably used as the first reaction gas. The carbon dioxide gas is precipitated as carbonate by reacting with the metal contaminants.

The gas may also include a second reaction gas that generates a gasified product by reacting with the impurities contained in the first ionic liquid IL1. In this case, when the first ionic liquid IL1 flowing through the connection pipe 135 contains the impurities, the second reaction gas generates the gasified product by reacting with the impurities contained in the first ionic liquid IL1. The gasified product is discharged by the exhaust device 82, for example, via the bypass pipe 139 inserted into the upper tank 137. This makes it possible to remove the impurities contained in the first ionic liquid IL1. For example, when the impurities contained in the first ionic liquid IL1 are halogens such as fluorine (F), chlorine (Cl), bromine (Br) or the like, a hydrogen-containing gas, such as water vapor (H₂O) or a hydrogen gas, may be suitably used as the second reaction gas. The hydrogen-containing gas generates hydrogen halide by reacting with the halogen.

The upper tank 137 stores the first ionic liquid IL1. The interior of the upper tank 137 is in communication with the first flow path 131a via a supply pipe 137a. The upper tank 137 is provided vertically above the first flow path 131a. As a result, the first ionic liquid IL1 flows from the interior of the upper tank 137 into the first flow path 131a by own weight thereof. The supply pipe 137a connects the upper tank 137 and the liquid supplier 131. Specifically, the supply pipe 137a has one end inserted into the interior of the upper tank 137 from the lower portion of the upper tank 137. For example, the other end of the supply pipe 137a is in communication with the first flow path 131a of the liquid supplier 131. The upper tank 137 is provided with a pressure sensor 137b configured to detects an internal pressure of the upper tank 137. A detection value by the pressure sensor 137b is sent to the controller 90. A heater 137c is attached to the upper tank 137. The heater 137c heats the upper tank 137.

The liquid replenisher 138 includes a source 138a, a supply pipe 138b, and a valve 138c. The source 138a is a source of the first ionic liquid IL1. The supply pipe 138b has one end connected to the source 138a and the other end inserted into the interior of the upper tank 137. The supply pipe 138b supplies the first ionic liquid IL1 to the interior of the upper tank 137. The valve 138c is disposed in the supply pipe 138b. The valve 138c switches the supply and cutoff of the first ionic liquid IL1 to the upper tank 137 by the opening and closing operation thereof. In this way, the liquid replenisher 138 supplies the first ionic liquid IL1 from the source 138a to the upper tank 137 via the supply pipe 138b, as necessary, by opening and closing the valve 138c. For example, the liquid replenisher 138 supplies the first ionic liquid IL1 to the upper tank 137 when the amount of the first ionic liquid IL1 stored in the upper tank 137 becomes small.

The bypass pipe 139 has one end inserted into the interior of the upper tank 137 from an upper portion of the upper tank 137 and the other end connected to the exhaust pipe 81. A valve 139a is provided in the bypass pipe 139. When the valve 139a is open, the interior of the upper tank 137 communicates with the interior of the exhaust pipe 81 via the bypass pipe 139. Thus, gas is exhausted from the interior of the upper tank 137 by the exhaust device 82 so that an internal pressure of the upper tank 137 becomes substantially the same as that of the chamber 10 or lower than the internal pressure of the chamber 10. As a result, the first ionic liquid IL1 stored inside the lower tank 133 is easily sent to the interior of the upper tank 137. The other end of the bypass pipe 139 may be connected to an exhaust line different from the exhaust pipe 81. In addition to the bypass pipe 139 or instead of the bypass pipe 139, a leak port may be provided. The leak port has one end inserted into the interior of the upper tank 137 and the other end open. The leak port discharges the gas in the upper tank 137 into an atmosphere in which the substrate processing apparatus 3 is installed.

Thus, the liquid circulator 130 sends the first ionic liquid IL1, which is recovered from the interior of the chamber 10 by the liquid recoverer 122 and stored in the lower tank 133, to the upper tank 137 via the connection pipe 125, and supplies the first ionic liquid IL1 to the interior of the chamber 10 by the liquid supplier. In other words, the liquid circulator 130 recovers the first ionic liquid IL1 from the interior of the chamber 10 and supplies the recovered first ionic liquid IL1 to the interior of the chamber 10, thereby circulating the first ionic liquid IL1.

As described above, the substrate processing apparatus 3 according to the third embodiment includes the liquid supplier 131, the liquid recoverer 132, the lower tank 133, the recovery pipe 134, the connection pipe 135, the gas supplier 136, the upper tank 137, the liquid replenisher 138, and the bypass pipe 139. The connection pipe 135 connects the interior of the upper tank 137 and the interior of the lower tank 133. The gas supplier 136 supplies the gas to the connection pipe 135 so as to send the first ionic liquid IL1 from the interior of the lower tank 133 to the interior of the upper tank 137 by the gas lift pump action of the rising gas. The first ionic liquid IL1 sent to the interior of the upper tank 137 is supplied to the first flow path 131a of the liquid supplier 131 by the supply pipe 137a. This makes it possible to recover the first ionic liquid IL1 from the interior of the chamber 10 and supply the recovered first ionic liquid IL1 to the interior of the chamber 10 without the mechanical power. That is, the first ionic liquid IL1 may be circulated without the mechanical power. In addition, like the substrate processing apparatus 1 according to the first embodiment, the substrate processing apparatus 3 according to the third embodiment may maintain throughput without reducing the operation time of the apparatus.

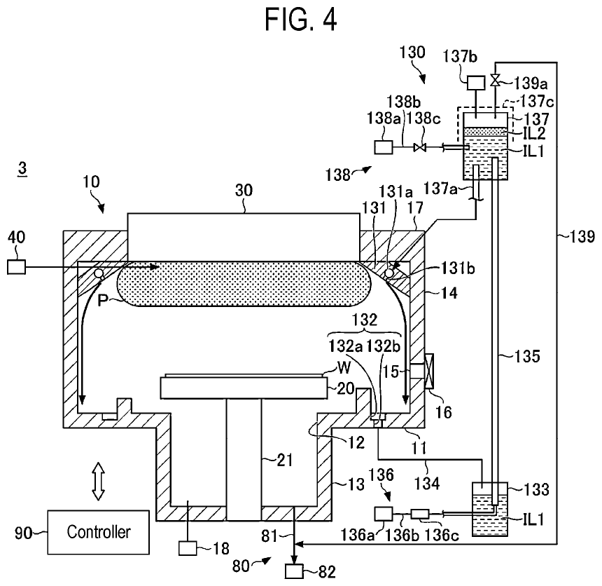

FIG. 4 is a schematic cross-sectional view illustrating a substrate processing apparatus according to Modification of the third embodiment. As illustrated in FIG. 4, the substrate processing apparatus 3 may be configured such that the upper tank 137 stores a second ionic liquid IL2 that is not mixed with the first ionic liquid IL1. In this case, the second ionic liquid IL2 may absorb impurities contained in the first ionic liquid IL1, for example, chlorine (Cl), water (H₂O) or the like, inside the upper tank 137. This makes it possible to improve clarifying efficiency of the impurities in the first ionic liquid IL1. For example, the second ionic liquid IL2 is supplied from the liquid replenisher 138 to the interior of the upper tank 137. The second ionic liquid IL2 may preferably be an ionic liquid having lower specific gravity and higher viscosity than those of the first ionic liquid IL1. In this case, an upper surface of the first ionic liquid IL1 may be covered with the second ionic liquid IL2, and the efficiency of absorbing moisture (H₂O) and the like may be increased. The impurities absorbed by the second ionic liquid IL2 may be vaporized by heating the second ionic liquid IL2 by the heater 137c and may be removed via the bypass pipe 139. Similarly to the upper tank 137, the lower tank 133 may also be configured to store the second ionic liquid IL2. Details of the second ionic liquid IL2 will be described later.

In the third embodiment, the case in which one end of the connection pipe 135 communicates with the interior of the lower tank 133 has been described. However, the present disclosure is not limited thereto. For example, like the substrate processing apparatus 1 according to the first embodiment, one end of the connection pipe 135 may communicate with the discharge hole 132b of the liquid recoverer 132. In this case, the lower tank 133 may be omitted.

### <Ionic Liquid>

Examples of the first ionic liquid IL1 and the second ionic liquid IL2 that may be used in the above embodiments will now be described. However, the first ionic liquid IL1 and the second ionic liquid IL2 are not limited to ionic liquids exemplified below.

An ionic liquid having hygroscopicity may preferably be used as the first ionic liquid IL1. Examples of the first ionic liquid IL1 may include 1-ethyl-3-methylimidazolium bis(trifluoromethanesulfonyl)imide, 1-n-octylpyridinium bis(trifluoromethanesulfonyl)imide, 1-n-butyl-1-methylpiperidinium bis(trifluoromethanesulfonyl)imide, 1,1,1-tri-n-butyl-1-n-dodecylphosphonium bis(trifluoromethanesulfonyl)imide, tributylhexadecylphosphonium 3-trimethylsilyl-1-propanesulfonate (BHDP·DSS), N,N-diethyl-N-methyl-N-(2-methoxyethyl)ammonium tetrafluoroborate (DEME·BF4), N-(2-methoxyethyl)-N-methylpyrrolidinium bis(trifluoromethanesulfonyl)imide (MEMP· TFSI), 1-ethyl-3-methylimidazolium acetate (EMI· AcO), and choline chloride-urea. Among these, DEME· BF4 may preferably be used.

As the second ionic liquid IL2, an ionic liquid having an oligomerized (polymer) cationic part may preferably be used. Such an ionic liquid has a low specific gravity and high viscosity. Thus, the ionic liquid may cover the upper surface of the first ionic liquid IL1 and increase the absorption efficiency of water (H₂O). As the second ionic liquid IL2, a mixed ionic liquid containing butylmethylimidazolium hexafluorophosphate or butylmethylimidazolium bis(trifluoromethanesulfonyl)imide may preferably be used.

It should be noted that the embodiments disclosed herein are exemplary in all respects and are not restrictive. The above-described embodiments may be omitted, replaced or modified in various forms without departing from the scope and spirit of the appended claims.

This international application claims priority based on Japanese Patent Application No. 2022-031761 filed on Mar. 2, 2022, and the entire disclosure of which is incorporated herein in its entirety by reference.

### EXPLANATION OF REFERENCE NUMERALS

1: substrate processing apparatus, 10: chamber, 110: liquid circulator, 111: liquid supplier, 112: liquid recoverer, 113: connection pipe, 114: gas supplier, 2 substrate processing apparatus, 120: liquid circulator, 121: liquid supplier, 122: liquid recoverer, 123: lower tank, 124: recovery pipe, 125: connection pipe, 126: gas supplier, 3: substrate processing apparatus, 130: liquid circulator, 131: liquid supplier, 132: liquid recoverer, 133: lower tank, 134: recovery pipe, 135: connection pipe, 136: gas supplier, 137: upper tank

1-10. (canceled)

11. A substrate processing apparatus, comprising:
a processing container in which a substrate to be processed is accommodated and substrate processing is performed:
a liquid supplier configured to supply a first ionic liquid to an interior of the processing container;
a liquid recoverer configured to recover the first ionic liquid from the interior of the processing container;
a connection pipe configured to connect the liquid recoverer to the liquid supplier; and
a gas supplier configured to supply gas to the connection pipe to send the first ionic liquid to the liquid supplier from the liquid recoverer by a gas lift pump action of the gas which rises.

12. The substrate processing apparatus of claim 11, wherein the liquid supplier includes a flow path through which the first ionic liquid sent from the liquid recoverer is supplied to the interior of the processing container.

13. The substrate processing apparatus of claim 12, wherein the liquid supplier includes an upper tank into which the connection pipe is inserted and configured to store the first ionic liquid, and
wherein an interior of the upper tank is in communication with the interior of the processing container by the flow path.

14. The substrate processing apparatus of claim 13, wherein the upper tank stores a second ionic liquid that is not mixed with the first ionic liquid and has a lower specific gravity than the first ionic liquid.

15. The substrate processing apparatus of claim 13, further comprising
an exhaust pipe configured to exhaust the interior of the processing container; and
a bypass pipe configured to allow the interior of the upper tank to communicate with an interior of the exhaust pipe.

16. The substrate processing apparatus of claim 13, wherein the liquid recoverer includes a lower tank provided vertically below the upper tank, and
wherein the lower tank is in communication with the interior of the processing container, and the connection pipe is inserted into the lower tank.

17. The substrate processing apparatus of claim 16, wherein the gas includes a first reaction gas precipitated by reacting with impurities contained in the first ionic liquid.

18. The substrate processing apparatus of claim 17, wherein the first reaction gas is a carbon dioxide gas.

19. The substrate processing apparatus of claim 16, wherein the gas includes a second reaction gas configured to generate a gasified product by reacting with impurities contained in the first ionic liquid.

20. The substrate processing apparatus of claim 19, wherein the second reaction gas is a hydrogen-containing gas.

21. The substrate processing apparatus of claim 11, wherein the gas includes a first reaction gas precipitated by reacting with impurities contained in the first ionic liquid.

22. The substrate processing apparatus of claim 21, wherein the first reaction gas is a carbon dioxide gas.

23. The substrate processing apparatus of claim 11, wherein the gas includes a second reaction gas configured to generate a gasified product by reacting with impurities contained in the first ionic liquid.

24. The substrate processing apparatus of claim 23, wherein the second reaction gas is a hydrogen-containing gas.
